(19) United States
(12) Patent Application Publication
(10) Pub. No.: US 2014/0224321 A1
(43) Pub. Date: Aug. 14, 2014

(54) SOLAR CELL AND METHOD OF FABRICATING THE SAME

(71) Applicant: Chin Woo Lim, Seoul (KR)

(72) Inventor: Chin Woo Lim, Seoul (KR)

(73) Assignee: LG INNOTEK CO., LTD., Seoul (KR)

(21) Appl. No.: 14/346,193

(22) PCT Filed: Sep. 20, 2012
(86) PCT No.: PCT/KR2012/007559

§ 371 Date: Mar. 20, 2014

(30) Foreign Application Priority Data
Sep. 20, 2011 (KR) 10-2011-0094486

(51) Int. Cl. H01L 31/0224

(52) U.S. Cl. CPC H01L 31/022441
USPC 136/256; 438/98

(57) ABSTRACT

A solar cell according to an embodiment includes a back electrode layer on a support substrate; a light absorbing layer on the back electrode layer; a front electrode layer on the light absorbing layer; and a plurality of metal nanowires on the front electrode layer, the metal nanowires being arranged a form of a mesh.

### TECHNICAL FIELD

The embodiment relates to a solar cell and a method of fabricating the same.

### BACKGROUND ART

Recently, the development of new renewable energy has become more important and interested due to the serious environmental pollution and the lack of fossil fuel. Among the new renewable energy, a solar cell is spotlighted as a pollution-free energy source for solving the future energy problem because it rarely causes environmental pollution and has the semi-permanent life span and there exists infinite resources for the solar cell.

Solar cells may be defined as devices to convert light energy into electrical energy by using a photovoltaic effect of generating electrons when light is incident onto a P-N junction diode. The solar cell may be classified into a silicon solar cell, a compound semiconductor solar cell mainly including a group I-III-VI compound or a group III-V compound, a dye-sensitized solar cell, and an organic solar cell according to materials constituting the junction diode.

A solar cell made from CIGS (CuInGaSe), which is one of group I-III-VI Chal-copyrite-based compound semiconductors, represents superior light absorption, higher photoelectric conversion efficiency with a thin thickness, and superior electro-optic stability, so the CIGS solar cell is spotlighted as a substitute for a conventional silicon solar cell.

In general, a CIGS solar cell can be prepared by sequentially forming a back electrode layer, a light absorbing layer, a buffer layer and a front electrode layer on a glass substrate. The substrate can be prepared by using various materials, such as soda lime glass, stainless steel and polyimide (PI). The back electrode layer mainly includes molybdenum (Mo) having low specific resistance and thermal expansion coefficient similar to that of the glass substrate.

The light absorbing layer is a P type semiconductor layer and mainly includes CuInSe2 or Cu(InxGal-x)Se2, which is obtained by replacing a part of In with Ga. The light absorbing layer can be formed through various processes, such as an evaporation process, a sputtering process, a selenization process or an electroplating process.

The buffer layer is disposed between the light absorbing layer and the front electrode layer, which represent great difference in lattice coefficient and energy bandgap, to form a superior junction therebetween. The buffer layer mainly includes cadmium sulfide prepared through chemical bath deposition (CBD).

The front electrode layer is an N type semiconductor layer and forms a PN junction with respect to the light absorbing layer together with the buffer layer. In addition, since the front electrode layer serves as a transparent electrode at a front surface of the solar cell, the front electrode layer mainly includes aluminum-doped zinc oxide (AZO) having the superior light transmittance and electric conductivity. The structure of the CIGS solar cell and fabrication method thereof are disclosed in Korean Patent Registration No. 10-0999810, in detail.

The doped zinc oxide, which is used as the front electrode layer in the related art, is thickly deposited at a low electric power for reducing the resistance, thereby not only decreasing the transmittance, but also increasing the process instability and the cost for raw material and the equipment investment. Further, as a width of the solar cell is increased, a series resistance Rs of the front electrode layer is increased, so that an electric conductivity is decreased.

### DISCLOSURE OF INVENTION

### Technical Problem

The embodiment provides a solar cell which may be easily fabricated and have improved electron capture ability and photoelectric conversion efficiency by disposing a plurality of metal nanowires in a mesh form on a front electrode layer, and a method for fabricating the same.

### Solution to Problem

According to the embodiment, there is provided a solar cell including a back electrode layer on a support substrate; a light absorbing layer on the back electrode layer; a front electrode layer on the light absorbing layer; and a plurality of metal nanowires on the front electrode layer, the metal nanowires being arranged in a form of a mesh.

A method for fabricating a solar cell according to the embodiment includes the steps of: forming a back electrode layer on a support substrate; forming a light absorbing layer on the back electrode layer; forming a front electrode layer on the light absorbing layer; and forming a plurality of metal nanowires on the front electrode layer in a form of a mesh.

### Advantageous Effects of Invention

According to the solar cell of the embodiment, a plurality of metal nanowires are disposed on the front electrode layer. The metal nanowires have electric characteristics superior to the front electrode layer. That is, the solar cell according to the embodiment may capture more electrons formed in the light absorbing layer as compared with the solar cell including only the front electrode layer according to the related art.

The metal wires in the solar cell according to the embodiment are fabricated in a nano-size, so that the light incident into the solar cell may be transmitted through the solar cell without being reflected from the solar cell. Further, since the metal nanowires are formed on the front electrode layer, the thickness of the front electrode layer may be reduced. That is, the solar cell according to the embodiment may be fabricated at a thinner thickness, thereby improving light transmittance.

Thus, the solar cell according to the embodiment may not only improve light transmittance, but also increase the electric conductivity and the photoelectric conversion efficiency.

### BRIEF DESCRIPTION OF DRAWINGS

FIG. 1 is a sectional view showing a solar cell according to the embodiment;

FIGS. 2 and 3 are perspective views showing a shape of the solar cell according to the embodiment; and

FIGS. 4 to 8 are sectional views illustrating a method for fabricating a solar cell according to the embodiment.

### MODE FOR THE INVENTION

In the description of the embodiments, it will be understood that, when a substrate, a layer, a film, or an electrode is referred to as being “on” or “under” another substrate, another layer, another film, or another electrode, it can be “directly” or “indirectly” on the other substrate, the other layer, the other film, or the other electrode, or one or more intervening layers may also be present. Such a position of each component has been described with reference to the drawings. The thickness and size of each component shown in the drawings may be exaggerated, omitted or schematically drawn for the purpose of convenience or clarity. In addition, the size of elements does not utterly reflect an actual size.

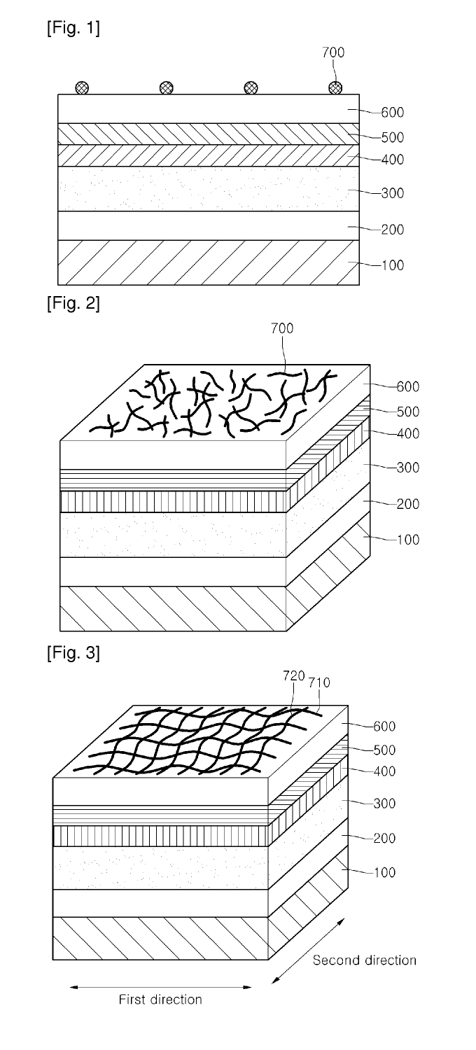

FIG. 1 is a sectional view showing a solar cell according to the embodiment. Referring to FIG. 1, the solar cell according to the embodiment includes a support substrate 100, a back electrode layer 200, a light absorbing layer 300, a buffer layer 400, a high-resistance buffer layer 500, a front electrode layer 600, and a plurality of metal nanowires 700.

The support substrate 100 has a plate shape and supports the back electrode layer 200, the light absorbing layer 300, the buffer layer 400, the high-resistance buffer layer 500, the front electrode layer 600 and the plurality of metal nanowires 700.

The support substrate 100 may be transparent, and rigid or flexible.

The support substrate 100 may be an insulator. For example, the support substrate 100 may be a glass substrate, a plastic substrate or a metal substrate. In detail, the support substrate 100 may be a soda lime glass substrate.

In addition, the support substrate 100 may include a ceramic substrate including alumina, stainless steel, or polymer having a flexible property.

The back electrode layer 200 is provided on the support substrate 100. The back electrode layer 200 is a conductive layer. The back electrode layer 200 may include one selected from the group consisting of molybdenum (Mo), gold (Au), aluminum (Al), chrome (Cr), tungsten (W), and copper (Cu). Among the above materials, the Mo has a thermal expansion coefficient similar to that of the support substrate 100, so the Mo may improve the adhesive property and prevent the back electrode layer 200 from being delaminated from the substrate 100. As described above, the characteristics required to the back electrode layer 200 may be satisfied overall.

Further, the back electrode layer 200 may include two layers or more. The layers may be formed of the same material or different materials, respectively.

The light absorbing layer 300 is provided on the back electrode layer 200. The light absorbing layer 300 includes a group I-III-VI compound. For example, the light absorbing layer 300 may have the CIGSS (Cu(IN,Ga)(Se,S)2) crystal structure, the CISS (Cu(IN)(Se,S)2) crystal structure or the CGSS (Cu(Ga)(Se,S)2) crystal structure.

The buffer layer 400 is provided on the light absorbing layer 300. The buffer layer 400 may include CdS, ZnS, InXSY or InXSeYZn(O, OH). The buffer layer 400 may have the thickness in the range of about 50 nm to about 150 nm and the energy bandgap in the range of about 2.2 eV to about 2.4 eV.

The high-resistance buffer layer 500 is disposed on the buffer layer 400. The high-resistance buffer layer 500 includes i-ZnO, which is not doped with impurities. The high-resistance buffer layer 500 may have the energy bandgap in the range of about 3.1 eV to about 3.3 eV. The high-resistance buffer layer 500 can be omitted.

The front electrode layer 600 may be provided on the light absorbing layer 300. For example, the front electrode layer 600 may directly make contact with the high-resistance buffer layer 500 formed on the light absorbing layer 300.

The front electrode layer 600 may include a transparent conductive material. In addition, the front electrode layer 600 may have the characteristics of an N type semiconductor. In this case, the front electrode layer 600 forms an N type semiconductor together with the buffer layer 400 to make a PN junction with the light absorbing layer 300 serving as a P type semiconductor layer. For instance, the front electrode layer 600 may include aluminum-doped zinc oxide (AZO).

The front electrode layer 600 may have a thickness in the range of about 100 nm to about 500 nm. The thickness of the front electrode layer 600 may be decreased by disposing the metal nanowires 700 on the front electrode layer 600. In detail, the thickness of the front electrode layer 600 may be in the range of 100 nm to 300 nm. Such a thickness of the front electrode layer 600 will be further described later together with the metal nanowires 700.

The metal nanowires 700 are disposed on the front electrode layer 600. The metal nanowires 700 may be disposed such that the metal nanowires 700 may directly make contact with the front electrode layer 600.

The metal nanowires 700 include conductive materials. The metal nanowires 700 allow migration of charges generated from the light absorbing layer 300 of the solar cell apparatus such that current can flow out of the solar cell apparatus. To this end, the metal nanowires 700 may have high electric conductivity and low specific resistance.

That is, the metal nanowires 700 are excellent in the capability of capturing electrons formed in the light absorbing layer 300 by solar light, so that a current loss may be minimized.

Further, the metal nanowires 700 may not only minimize the current loss, but also decrease the thickness of the front electrode layer 600. That is, by using the metal nanowires 700 having excellent electric conductivity, the front electrode layer 600 may be formed at a thinner thickness, so that the solar cell may be manufactured at a thin thickness.

The metal nanowires 700 can be formed by using various metals without any specific limitation if the metals may be generally used in the art to form an electrode. For example, the metal nanowires 700 may include a material selected from the group consisting of Ag, Al, Ca, Cr, Fe, Co, Ni, Cu, Mo, Ru, In, W and a combination thereof. In detail, the metal nanowires 700 may include Ag, but the embodiment is not limited thereto.

In the solar cell according to the embodiment, the metal nanowires may be formed in a nanometer size. That is, the diameter of each metal nanowire 700 may be in the range of about 20 nm to about 55 nm, and the length of each metal nanowire 700 may be in the range of about 30 μm to 60 μm. Although the metal nanowires 700 may be formed be have a diameter of several tens of nanometers, the metal nanowires 700 having superior electric characteristics may be obtained.

Further, the metal nanowires 700 having the nanometer size may easily transmit solar light incident into the solar cell without reflecting or blocking the light. Thus, the solar cell according to the embodiment may not only improve light transmittance, but also increase the electric conductivity and the photoelectric conversion efficiency.

FIGS. 2 and 3 are perspective views showing a shape of the solar cell according to the embodiment.

As shown in FIG. 2, the metal nanowires 700 may be irregularly distributed, or, as shown in FIG. 3, may be regularly aligned. For example, the plurality of metal nanowires 700 may be prepared in the form of a mesh or grid. When the metal nanowires 700 have the mesh shape, the metal nanowires 700 may include a plurality of first metal nanowires 710 extending in a first direction, and a plurality of second metal nanowires 720 extending in a second direction crossing the first direction.

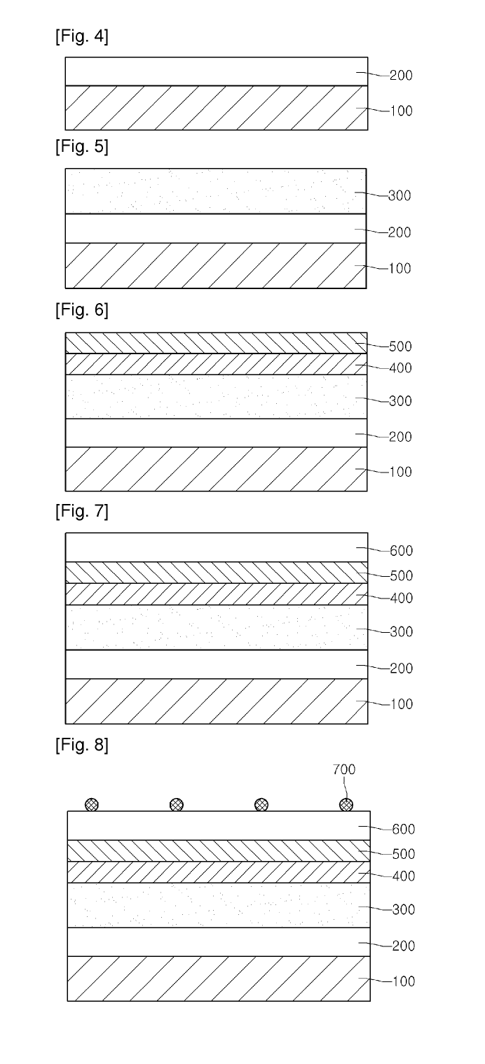

FIGS. 4 to 8 are sectional views illustrating a method for fabricating a solar cell according to the embodiment. The description related to the fabricating method will be made based on the above description about the solar cell. The above description about the solar cell will be essentially incorporated herein by reference.

Referring to FIG. 4, the back electrode layer 200 may be formed on the support substrate 100. The back electrode layer 200 may be deposited by using Mo. The back electrode layer 200 may be formed through a PVD (physical vapor deposition) process or a plating process.

In addition, an additional layer, such as a diffusion barrier layer, may be formed between the support substrate 100 and the back electrode layer 200.

Referring to FIG. 5, the light absorbing layer 300 is formed on the back electrode layer 200.

The light absorbing layer 300 may be formed through various schemes such as a scheme of forming a Cu(In,Ga)Se2 (CIGS) based light absorbing layer 300 by simultaneously or separately evaporating Cu, In, Ga, and Se and a scheme of performing a selenization process after a metal precursor layer has been formed.

Regarding the details of the selenization process after the formation of the metal precursor layer, the metal precursor layer is formed on the back electrode layer 200 through a sputtering process employing a Cu target, an In target, or a Ga target.

Then, the metal precursor layer is subject to the selenization process so that the Cu (In, Ga) Se2 (CIGS) based light absorbing layer 300 is formed.

In addition, the sputtering process employing the Cu target, the In target, and the Ga target and the selenization process may be simultaneously performed.

Further, a CIS or a CIG based light absorbing layer 300 may be formed through the sputtering process employing only Cu and In targets or only Cu and Ga targets and the selenization process.

Referring to FIG. 6, the buffer layer 400 and the high-resistance buffer layer 500 are formed on the light absorbing layer 300.

Thereafter, the buffer layer 400 may be formed by depositing CdS on the light absorbing layer 300 through a CBD (Chemical Bath Deposition) scheme.

In addition, ZnO may be deposited on the buffering layer 400 through the sputtering process, thereby forming the high-resistance buffer layer 500.

Referring to FIG. 7, the front electrode layer 600 is formed on the high-resistance buffer layer 500. In order to form the front electrode layer 600, a transparent conductive material is laminated on the high-resistance buffer layer 500. For example, the transparent conductive material may include zinc oxide doped with aluminum or boron. The process for forming the front electrode layer 600 may be performed at the temperature in the range of the normal temperature to 300° C.

Referring to FIG. 8, the metal nanowires 700 are formed on the front electrode layer 600. The metal nanowires 700 may be fabricated through a process including a step S10 of heating a solvent; a step S20 of adding a capping agent and a catalyst into the solvent and heating the solvent; and a step S30 of forming the metal nanowires 700 by adding a metal compound into the solvent.

In the step S10 of heating the solvent, the solvent is heated at the reaction temperature suitable to form the metal nanowires 700. The solvent may include polyol. The polyol may serve as a mile reducing agent as well as a solvent of mixing different materials, thereby promoting the formation of the metal nanowires. The polyol may include ethylene glycol (EG), propylene glycol (PG), dipropylene glycol, glycerin, 1,3-propanediol, glycerol or glucose.

The reaction temperature may be variously adjusted based on the type and the characteristics of the solvent and the metal compound. When silver nanowires are formed by using the propylene glycol (PG) as the solvent, the reaction temperature may be in the range of about 80° C. to about 140° C. When the reaction temperature is less than 80° C., the reaction rate is low so that the reaction is not smoothly performed, lengthening the process time. Further, when the reaction temperature exceeds 140° C., it may be difficult to have a metal nanowire shape due to the cohesion and the product yield may be decreased.

In the step S20 of adding the capping agent and the catalyst to the solvent, the capping agent and the catalyst for inducing the formation of the metal nanowires are added to the solvent. If reduction for the formation of the metal nanowires is too rapid, metals may cohere, so that the wire shape may not be formed. Accordingly, the capping agent prevents the metals from cohering by properly dispersing materials contained in the solvent.

The capping agent may include various materials. For example, the capping agent may include polyvinylpyrrolidone (PVP), polyvinyl alcohol (PVA), cetyl trimethyl ammonium bromide (CTAB), cetyl trimethyl ammonium chloride (CTAC), and polyacrylamide (PAA).

The capping agent may be added in the content of 60 weight part to 330 weight part based on 100 weight part of the metal compound. If the capping agent is added in the content less than 60 weight part, the cohesion cannot be sufficiently prevented. If the capping agent is added in the content exceeding 330 weight part, metal nano-particles may be formed in a spherical shape or a cube shape, and the capping agent remains in the manufactured metal nano-wire, so that the electrical conductivity may be degraded.

The catalyst may include a material selected from the group consisting of AgCl, KBr, KI, CuCl2, PtCl2, H2PtCl4, H2PtCl6, AuCl, AuCl3, HAuCl4, HAuCl2, and a combination thereof. The catalyst may be added in the content of 0.005 weight part to 0.5 weight part based on 100 weight part of the metal compound. If the catalyst is added in the content less than 0.005 weight part, reaction may not be sufficiently accelerated. In addition, if the catalyst is added in the content exceeding 0.5 weight part, the reduction of silver is rapidly performed, so that metal nanoparticles may be created, or the diameter of the nanowire may be increased and the length of the nanowire may be shortened. In addition, the catalyst remains in the manufactured metal nanowire, so that the electrical conductivity may be degraded.

In the step S30 of adding the metal compound to the solvent, a reaction solution is formed by adding the metal compound to the solvent. In this case, the metal compound melted in a separate solvent may be added to the solvent having the capping agent and the catalyst. The separate solvent may include material identical to or different from material used in the initial stage. The metal compound may be added after a predetermined time elapses from a time in which the catalyst is added. This is required to stabilize a temperature to a desirable reaction temperature.

Here, the metal compound includes a compound including metal used to manufacture a desirable metal nano-wire. In order to form a silver nano-wire, the metal compound may include AgCl, AgNO3 or KAg(CN)2. As described above, if the metal compound is added to the solvent having the capping agent and the catalyst, reaction occurs so that the forming of the metal nano-wire is started.

Then, in the step S40 of adding the normal-temperature solvent to the solvent, the normal-temperature solvent is added to the solvent in which reaction is started. The normal-temperature solvent may include material identical to or different from the material used in the initial stage. For example, the normal-temperature solvent may include polyol such as ethylene glycol and propylene glycol.

As the solvent, in which the reaction is started, is continuously heated in order to maintain the constant reaction temperature, the temperature may be increased in the process of the reaction. As described above, the reaction temperature may be more constantly maintained by temporarily degrading the temperature of the solvent by adding the normal-temperature solvent to the solvent in which the reaction is started.

The step S40 of adding the normal-temperature solvent may be performed one time or several times by taking the reaction time and the temperature of the reaction solution into consideration. Since the step S40 of adding the normal-temperature solvent is not essential, the step S40 may be omitted.

Lastly, the step S50 of refining the metal nanowire may be additionally performed. In more detail, if acetone serving as a non-polar solvent is added to the reaction solution rather than water, the metal nano-wire is deposited at the lower portion of the solution due to the capping agent remaining on the surface of the metal nano-wire. This is because the capping agent is not dissolved in the acetone, but cohered and deposited although the capping agent is sufficiently dissolved in the solvent. Thereafter, when the upper portion of the solution is discarded, a portion of the capping agent and nanoparticles are removed.

If distill water is added to the remaining solution, metal nanowires and metal nanoparticles are dispersed. In addition, if acetone is more added, the metal nanowires are deposited, and the metal nano-particles are dispersed in the upper portion of the solution. Thereafter, if the upper portion of the solution is discarded, a part of the capping agent and the cohered metal nano-particles are discarded. After collecting the metal nanowires by repeatedly performing the above processes, the metal nanowires are stored in the distill water. The metal nanowires can be prevented from re-cohering by storing the metal nanowires in the distill water.

According to the solar cell of the embodiment, the metal nanowires 700 are disposed on the front electrode layer 600. The metal nanowires 700 have electric characteristics superior to that of the front electrode layer. That is, the solar cell according to the embodiment may capture more electrons formed in the light absorbing layer as compared with the solar cell including only the front electrode layer according to the related art, so that the photoelectric conversion efficiency may be improved.

The method for fabricating a solar cell according to the embodiment may fabricate the metal nanowires in a nano-size as described above, so that light incident into the solar cell may be transmitted without being reflected. Further, since the metal nanowires are formed, the thickness of the front electrode layer may be reduced. Thus, the solar cell according to the embodiment may be fabricated at a thinner thickness.

Any reference in this specification to “one embodiment,” “an embodiment,” “example embodiment,” etc., means that a particular feature, structure, or characteristic described in connection with the embodiment is included in at least one embodiment of the invention. The appearances of such phrases in various places in the specification are not necessarily all referring to the same embodiment. Further, when a particular feature, structure, or characteristic is described in connection with any embodiment, it is submitted that it is within the purview of one skilled in the art to effect such feature, structure, or characteristic in connection with other ones of the embodiments.

Although embodiments have been described with reference to a number of illustrative embodiments thereof, it should be understood that numerous other modifications and embodiments can be devised by those skilled in the art that will fall within the spirit and scope of the principles of this disclosure. More particularly, various variations and modifications are possible in the component parts and/or arrangements of the subject combination arrangement within the scope of the disclosure, the drawings and the appended claims. In addition to variations and modifications in the component parts and/or arrangements, alternative uses will also be apparent to those skilled in the art.

1. A solar cell comprising:
back electrode layer on a support substrate;
a light absorbing layer on the back electrode layer;
a front electrode layer on the light absorbing layer; and
a plurality of metal nanowires on the front electrode layer, the metal nanowires being arranged in a form of a mesh or grid.

2. The solar cell of claim 1, wherein each of the metal nanowires has a diameter in a range of 20 nm to 55 nm and a length in a range of 30 μm to 60 μm.

3. The solar cell of claim 1, wherein the metal nanowires include a material selected from the group consisting of silver (Ag), aluminum (Al), calcium (Ca), chrome (Cr), iron (Fe), cobalt (Co), nickel (Ni), copper (Cu), molybdenum (Mo), ruthenium (Ru), indium (In), tungsten (W) and a combination thereof.

4. The solar cell of claim 1, wherein the metal nanowires include:
a plurality of first metal nanowires extending in a first direction; and
a plurality of second metal nanowires extending in a second direction crossing the first direction.

5. The solar cell of claim 1, wherein the front electrode layer has a thickness in a range of 100 nm to 500 nm.

6. A method for fabricating a solar cell, the method comprising:
forming a back electrode layer on a support substrate;
forming a light absorbing layer on the back electrode layer;
forming a front electrode layer on the light absorbing layer; and
forming a plurality of metal nanowires on the front electrode layer in a form of a mesh.

7. The method of claim 6, wherein the forming of the metal nanowires includes:
heating a solvent;
adding a capping agent and a catalyst into the solvent and heating the solvent; and
forming the metal nanowires by adding a metal compound into the solvent.

8. The method claim 7, further comprising refining the metal nanowires after the forming of the metal nanowires.

9. The method of claim 1, wherein the capping agent includes a material selected from the group consisting of polyvinylpyrrolidone (PVP), polyvinyl alcohol (PVA), cetyl trimethyl ammonium bromide (CTAB), cetyl trimethyl ammonium chloride (CTAC), polyacrylamide (PAA), and a combination thereof

10. The method of claim 7, wherein the capping agent is added by a content of 60 weight part to 330 weight part based on 100 weight part of a metal compound.

11. The method of claim 7, wherein the catalyst includes a material selected from the group consisting of AgCl, KBr, KI, CuCl2, PtCl2, H2PtCl4, H2PtCl6, AuCl, AuCl3, HAuCl4, HAuCl2 and a combination thereof.

12. The method of claim 7, wherein the catalyst is added by a content of 0.005 weight part to 0.5 weight part based on 100 weight part of a metal compound.

13. The method of claim 7, wherein the solvent includes a material selected from the group consisting of propylene glycol (PG), 1,3-propanediol, dipropylene glycol, and a combination thereof.

14. The method of claim 6, wherein the metal nanowires include:
a plurality of first metal nanowires extending in a first direction; and
a plurality of second metal nanowires extending in a second direction crossing the first direction.
